(19) United States
(12) Patent Application Publication
(10) Pub. No.: US 2026/0180684 A1
(43) Pub. Date: Jun. 25, 2026

(54) MULTI-CHANNEL OPTICAL TRANSCEIVER

(71) Applicant: ELECTRONICS AND TELECOMMUNICATIONS RESEARCH INSTITUTE, Daejeon (KR)

(72) Inventors: Won-Bae Kwon, Daejeon (KR); Jong Jin Lee, Daejeon (KR); Eun Kyu Kang, Daejeon (KR); Soo Yong Jung, Daejeon (KR); Haechung Kang, Daejeon (KR); Sangjin Kwon, Daejeon (KR); Myunghwan Kim, Daejeon (KR); Dae Woong Moon, Daejeon (KR); Gye Sul Cho, Daejeon (KR)

(21) Appl. No.: 19/394,305

(22) Filed: Nov. 19, 2025

(30) Foreign Application Priority Data
Dec. 19, 2024 (KR) 10-2024-0191269

(51) Int. Cl. H04B 10/40; H04B 10/50; H04B 10/69; H04B 10/80; H05K 1/14; H05K 1/18

(52) U.S. Cl. CPC H04B 10/40; H04B 10/506; H04B 10/6932; H04B 10/801; H05K 1/147; H05K 1/181; H05K 2201/1003; H05K 2201/10121; H05K 2201/10378

(57) ABSTRACT

Disclosed is a multi-channel optical transceiver. The multi-channel optical transceiver includes a printed circuit board (PCB), an optical reception module embedded in the PCB and configured to convert a received optical signal into an electrical reception signal, an optical transmission module mounted on a bottom of the PCB and configured to output an electrical transmission signal by modulating the electrical transmission signal into an optical signal, a signal processing module configured to process the electrical transmission signal and the electrical reception signal, a flexible printed circuit board (FPCB) configured to electrically connect the signal processing module and the optical transmission module, and a glass interposer mount configured to transmit the electrical reception signal from the optical reception module to the signal processing module.

### BACKGROUND

### 1. Technical Field

The present disclosure relates to an optical module structure of a multi-channel optical transceiver for minimizing a transmission loss.

### 2. Related Art

As data traffic is suddenly increased due to an increase in demands for intelligent services and cloud services, such as artificial intelligence and big data, a multi-channel optical transceiver having a 400 Giga class or more, which can transmit a large amount of data, is required within a data center.

According to conventional technology, an electrical signal that is output from a preamplifier passes through multiple vias and a long Rx transmission line, resulting in an increased RF insertion loss and reflection loss, which causes the electrical signal to be attenuated and distorted.

### SUMMARY

Various embodiments are directed to improving an electrical bandwidth by a minimized transmission line length and reducing the size of an optical module and manufacturing costs because a glass interposer that is made of a transparent material, has a low high-frequency transmission loss, and can easily identify that an electrode is applied to an optical reception module within a multi-channel optical transceiver so that the electrodes of a signal processing module can be connected to parts, such as an optical element, within an optical reception module package at the shortest distance by replacing the through substrate and flexible substrate of the optical reception module package.

Technical objects to be achieved by the present disclosure are not limited to the aforementioned object, and the other objects not described above may be evidently understood from the following description by a person having ordinary knowledge in the art to which the present disclosure pertains.

This specification proposes a multi-channel optical transceiver. The multi-channel optical transceiver is a multi-channel optical transceiver including a printed circuit board (PCB) 110, an optical reception module 120 embedded in the PCB 110 and configured to convert a received optical signal into an electrical reception signal, an optical transmission module 130 mounted on the bottom of the PCB 110 and configured to output an electrical transmission signal by modulating the electrical transmission signal into an optical signal, a signal processing module (electrical sub-assembly (ESA)) 140 configured to process the electrical transmission signal and the electrical reception signal, and a flexible printed circuit board (FPCB) 119 configured to electrically connect the signal processing module 140 and the optical transmission module 130. The optical reception module 120 may include a pre-amplifier 125 mounted over the PCB 110, a glass interposer mount 150 mounted over the pre-amplifier 125 and having a transmission line electrode 112 electrically connected to the signal processing module 140 formed at the bottom thereof, and an optical detector 123 mounted over the glass interposer mount 150 and configured to detect a received optical signal and to output the detected optical signal to the pre-amplifier 125 by converting the detected optical signal into an electrical reception signal. The pre-amplifier 125 may transmit the electrical reception signal received from the optical detector 123 to the signal processing module 140 through the transmission line electrode 112 by amplifying the electrical reception signal.

Furthermore, this specification proposes a multi-channel optical transceiver. The multi-channel optical transceiver is a multi-channel optical transceiver including a printed circuit board (PCB) 110, an optical reception module 120 embedded in the PCB 110 and configured to convert a received optical signal into an electrical reception signal, an optical transmission module 130 mounted on the bottom of the PCB 110 and configured to output an electrical transmission signal by modulating the electrical transmission signal into an optical signal, a signal processing module (electrical sub-assembly (ESA) 140 configured to process the electrical transmission signal and the electrical reception signal, and a flexible printed circuit board (FPCB) 119 configured to electrically connect the signal processing module 140 and the optical transmission module 130. The optical reception module 120 may include a pre-amplifier 125 mounted over the PCB 110, a glass interposer mount 150 mounted over the pre-amplifier 125 and including a transmission line electrode 112-1 formed over the pre-amplifier 125 and configured to electrically connect the pre-amplifier 125 and the signal processing module 140, and an optical detector 123 mounted over the glass interposer mount 150 and configured to detect a received optical signal and to output the detected optical signal to the pre-amplifier 125 by converting the detected optical signal into an electrical reception signal. The pre-amplifier 125 may transmit the electrical reception signal received from the optical detector 123 to the signal processing module 140 through the transmission line electrode 112 by amplifying the electrical reception signal.

According to an embodiment disclosed in this specification, it is possible to improve an electrical bandwidth by a minimized transmission line length and reduce the size of an optical module and manufacturing costs because a glass interposer that is made of a transparent material, has a low high-frequency transmission loss, and can easily identify an electrode is applied to an optical reception module within a multi-channel optical transceiver so that the electrodes of a signal processing module can be connected to parts, such as an optical element, within an optical reception module package at the shortest distance by replacing the through substrate and flexible substrate of the optical reception module package.

Furthermore, according to an embodiment disclosed in this specification, it is possible to reduce a process time compared to a thermal conduction soldering process using a heating plate method and to minimize thermal stress around a bonding portion because the glass interposer that is transparent and has a low transmission loss is applied to the optical reception module within the multi-channel optical transceiver.

Effects of the present disclosure which may be obtained in the present disclosure are not limited to the aforementioned effects, and the other effects not described above may be evidently understood by a person having ordinary knowledge in the art to which the present disclosure pertains from the following description.

### BRIEF DESCRIPTION OF THE DRAWINGS

The following drawings attached to this specification illustrate preferred embodiments of the present disclosure, and help to further understand the technical spirit of the present disclosure along with the aforementioned contents of the disclosure. Accordingly, the present disclosure should not be construed as being limited to only contents described in such drawings.

FIG. 1 is a top view of a conventional multi-channel optical transceiver.

FIG. 2 is a side view of the multi-channel optical transceiver illustrated in FIG. 1.

FIG. 3 is a top view of a multi-channel optical transceiver according to an embodiment.

FIG. 4 is a side view of the multi-channel optical transceiver illustrated in FIG. 3.

FIG. 5 is a top view of a multi-layer glass interposer mount according to an embodiment.

FIG. 6 is a side view of the multi-layer glass interposer mount illustrated in FIG. 5.

FIG. 7 is a diagram describing a local laser soldering process between the electrodes of glass interposers using a high-output laser.

FIG. 8 is a side view of a multi-channel optical transceiver according to another embodiment.

### DETAILED DESCRIPTION

It is to be noted that technological terms used in this specification are used to describe only specific embodiments and are not intended to limit this specification. Furthermore, the technological terms used in this specification should be construed as having meanings that are commonly understood by those skilled in the art to which this specification pertains unless especially defined as different meanings otherwise in this specification, and should not be construed as having excessively comprehensive meanings or excessively reduced meanings. Furthermore, if the technological term used in this specification is a wrong technological term that does not precisely represent the spirit of a technology disclosed in this specification, the technological term should be replaced with a technological term which may be correctly understood by a person having ordinary knowledge in the field disclosed in this specification and understood. Furthermore, common terms used in this specification should be interpreted in accordance with the definition of dictionaries or in accordance with the context, and should not be construed as having excessively reduced meanings.

Hereinafter, embodiments according to the present disclosure are described in detail with reference to the accompanying drawings. The same or similar component is assigned the same reference numeral regardless of its reference numeral, and a redundant description thereof is omitted. It is to be noted that the suffixes of components used in the following description, such as a “module” and a “unit”, are assigned or interchangeable with each other by taking into consideration only the ease of writing this specification, but in themselves are not particularly given distinct meanings and roles. Furthermore, it is to be understood that the accompanying drawings are merely intended to make easily understood the embodiments disclosed in this specification, and the technical spirit disclosed in this specification is not restricted by the accompanying drawings and includes all changes, equivalents, and substitutions which fall within the spirit and technical scope of this specification.

Terms including ordinal numbers, such as a “first” and a “second”, which are used in this specification, may be used to describe various components, but the components are not restricted by the terms. The terms are used to only distinguish one component from the other components. For example, a first component may be named a second component without departing from the scope of rights of this specification. Likewise, the second component may be named the first component.

When it is described that one component is “connected” or “coupled” the other component, it should be understood that one component may be directly connected or coupled to the other component, but a third component may exist between the two components. In contrast, when it is described that one component is “directly connected” or “directly coupled” to the other component, it should be understood that a third component does not exist between the two components.

An expression of the singular number includes an expression of the plural number unless clearly defined otherwise in the context.

In this specification, it is to be understood that a term, such as “include” or “have”, is intended to designate that a characteristic, a number, a step, an operation, a component, a part or a combination of them described in the specification is present, and does not exclude the presence or addition possibility of one or more other characteristics, numbers, steps, operations, components, parts, or combinations of them in advance.

Hereinafter, in order to help understanding of those skilled in the art, a proposed background of the present disclosure is first described and an embodiment of the present disclosure is then described.

As data traffic is suddenly increased due to an increase in demands for intelligent services and cloud services, such as artificial intelligence and big data, a multi-channel optical transceiver having a 400 Giga class or more, which can transmit a large amount of data, is required within a data center.

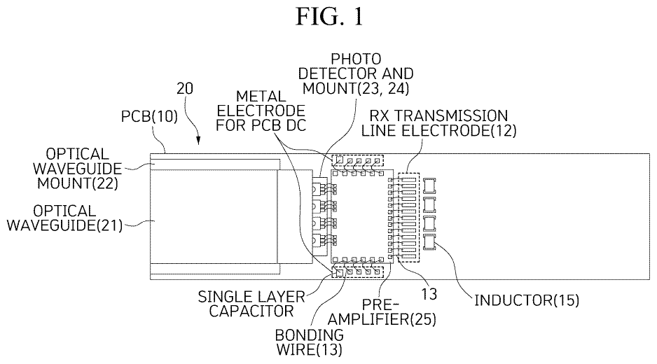

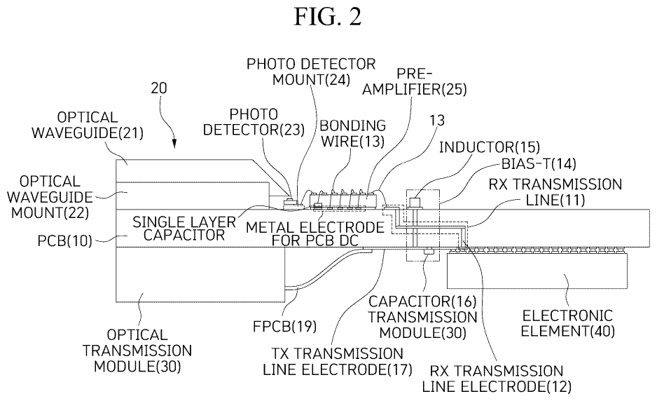

In general, a conventional 400 Giga class optical transceiver has a pluggable shape standard, and has a structure in which a signal processing module (electrical sub-assembly (ESA)), an optical transmission module (transmitter optical sub-assemblies (TOSAs)), and optical reception module (receiver optical sub-assemblies (ROSAs)) are electrically connected by using a flexible printed circuit board (FPCB). Furthermore, if the optical transceiver has a small form factor, such as QSFP-DD, in order to improve the degree of integration, the optical transceiver is designed to have a structure in which the signal processing module and the TOSAs are electrically connected by using the FPCB and the ROSAs are embedded in the signal processing module, as illustrated in FIGS. 1 and 2. Such an embedded structure can reduce the length of the transmission line of an optical reception unit because an optical reception module can be implemented within the PCB even without the FPCB and a ceramic feedthrough within the optical reception module package, compared to the existing structure in which the optical reception module and the FPCB are connected, and can maximize an electrical bandwidth by minimizing a reflection loss having a high frequency signal according to impedance mismatching that essentially occurs at a bonding part for the electrode of the PCB and the electrode of the FPCB and a bonding part for the electrode of the ceramic feedthrough and the electrode of the FPCB. Furthermore, the embedded structure has an advantage in that the embedded structure can be implemented at a relatively low cost because an expensive ceramic feedthrough is not used.

Referring to FIGS. 1 to 2, in a conventional structure in which an optical reception module 20 has been embedded, the optical reception module 20 and an optical transmission module 30 are disposed at the top and bottom of a PCB 10. In the optical reception module 20, in order to convert an optical signal into an electrical signal after channel division or wavelength division, an optical waveguide 21 and multiple optical detectors 23 are disposed the top of the PCB 10 by using an optical waveguide mount 22 and an optical detector mount 24, respectively. Furthermore, in the optical reception module 20, in order to correct signal distortion attributable to the amplification of a 100 Giga class PAM4 signal per channel and an RF transmission loss, a pre-amplifier 25 and a DSP electronic element 40 are disposed at the top and bottom of the PCB 10, respectively. The pre-amplifier 25 and the DSP electronic element 40 are electrically connected by using an Rx transmission line electrode 12 of an optical reception unit (Rx) transmission line 11 including a via and bonding wires 13. In this case, it is necessary to minimize the length of the bonding wire 13 because an RF insertion loss is increased due to an inductance increase depending on the lengths of the bonding wires 13 between the optical detector 23 and the pre-amplifier 25 and between the pre-amplifier 25 and the Rx transmission line electrode 12. The optical transmission module 30 includes a bias-T 14 configured by using an inductor 15 and a capacitor 16 within an optical transmission unit (Tx) transmission line and has a Tx transmission line electrode 17 and the DSP electronic element 40 electrically connected in order to input a bias voltage and a high-speed data signal.

A 400 Giga class or more optical module having a small form factor, such as QSFP-DD, has a limited width of a PCB. Accordingly, as illustrated in FIGS. 1 and 2, the inductor 15 to which a DC bias voltage is connected is disposed on the other side of the Tx transmission line (including the Tx transmission line electrode 17). In such a case, the Rx transmission line electrode 12 is disposed in an internal layer of the PCB 10 and at the top through the via so that the Rx transmission line electrode 12 is disposed by avoiding the inductor 15. Accordingly, the length of the Rx transmission line 11 is increased. That is, there is a problem in that an electrical signal is attenuated and distorted due to an increase in an RF insertion loss and a reflection loss because the electrical signal output by the pre-amplifier 25 passes through multiple vias and the long Rx transmission line 11.

The aforementioned contents are provided to merely help understanding of the background technology of technical spirit of the present disclosure. Accordingly, the aforementioned contents cannot be understood as contents corresponding to a prior art known to those skilled in the art to which the present disclosure pertains.

Embodiments of the present disclosure can improve an electrical bandwidth by minimizing a high frequency transmission loss because the electrode of a pre-amplifier, the electrode of a glass interposer, the electrode of a glass interposer, and the electrode of a signal processing module are directly bonded within an optical reception module of an optical transceiver. Furthermore, it is possible to maximize an electrical bandwidth by optimizing impedance matching through alignment optimization between the electrodes of a glass interposer and a signal processing module within an optical reception module and local laser bonding. This technology is an optical module packaging technology based on local laser bonding. Hereinafter, embodiments of the present disclosure are described in detail with reference to the accompanying drawings.

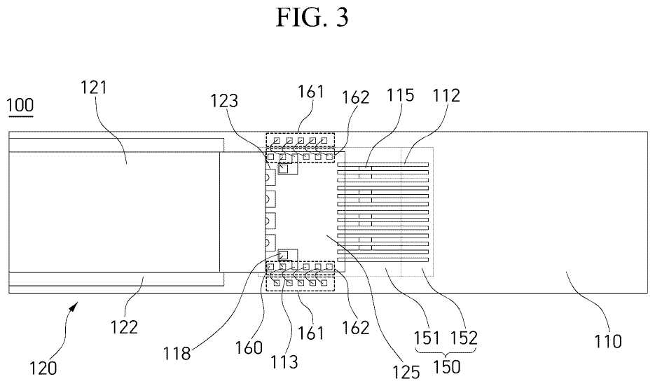

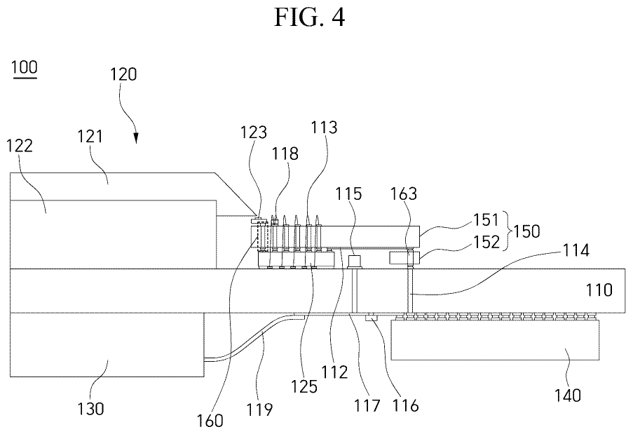

FIG. 3 is a top view of a multi-channel optical transceiver according to an embodiment. FIG. 4 is a side view of the multi-channel optical transceiver

Referring to FIGS. 3 to 4, a multi-channel optical transceiver 100 according to an embodiment basically includes a signal processing module 140 on which an electronic element, such as a DSP, is mounted, an optical transmission module 130 that optically modulates and outputs an electrical signal, an FPCB 119 that electrically connects a signal processing module and the optical transmission module 130, and an embedded optical reception module 120 that converts an optical signal into an electrical signal. In the optical reception module 120, an optical waveguide 121 having a slope so that the wavelength of a wavelength-multiplexed optical signal is divided and the wavelength-multiplexed optical signal is perpendicularly incident on an optical detector 123 for each channel and an optical waveguide mount 122 are mounted on a PCB 110. The slope of the optical waveguide 121 may have a surface inclined at an angle of about 41 to 42° in order to minimize back reflection while satisfying total reflection, for example.

A pre-amplifier 125 is mounted on the PCB 110 by using epoxy in order to convert a current signal output by the optical detector 123 into a voltage signal and to amplify an electrical signal. A multi-layer glass interposer mount 150 including a first glass interposer 151 and a second glass interposer 152 is applied to an Rx transmission line in order to minimize an RF transmission loss while avoiding an inductor 115. The inductor 115 is connected to a Tx transmission line electrode 117 through a via that penetrates the PCB 110, and constitutes a bias-T along with a capacitor 116 mounted under the PCB 110. Such a structure has an advantage in that it can maximize an electrical bandwidth by minimizing an RF insertion loss and a reflection loss because the multi-layer glass interposer mount 150 is mounted over the pre-amplifier 125 and the length of the Rx transmission line is minimized without a bonding wire. Furthermore, in order to remove power noise of the pre-amplifier 125, a single layer capacitor 118 for bypass needs to be disposed around the pre-amplifier 125 as close as possible. The single layer capacitor 118 may be disposed around the pre-amplifier 125 as close as possible by disposing the single layer capacitor 118 at the top of the first glass interposer 151.

The first glass interposer 151 includes an RF through metal electrode 160 that electrically connects the electrode of the optical detector 123 and the electrode of the pre-amplifier 125 and a through metal electrode 162 for DC that connects a power source for the pre-amplifier 125 and a ground and a pin for RSSI monitoring and the PCB 110 in addition to an RF transmission line that is connected between the pre-amplifier 125 and the signal processing module 140. The RF through metal electrode 160 and the through metal electrode 162 for DC included in the first glass interposer 151 are bonded to the metal electrode of the optical detector 123 and the metal electrode of the pre-amplifier 125 through a soldering process. The through metal electrode 162 for DC of the first glass interposer 151 and the single layer capacitor 118 are electrically connected to a metal electrode 161 for PCB DC through bonding wires. The second glass interposer 152 has an RF through electrode 163 formed therein in order to connect a transmission line electrode 112 of the first glass interposer 151 to the input stage of the signal processing module 140. An Rx through metal electrode 114 that penetrates the PCB is formed at a location of the PCB 110 corresponding to one end of the RF through electrode 163.

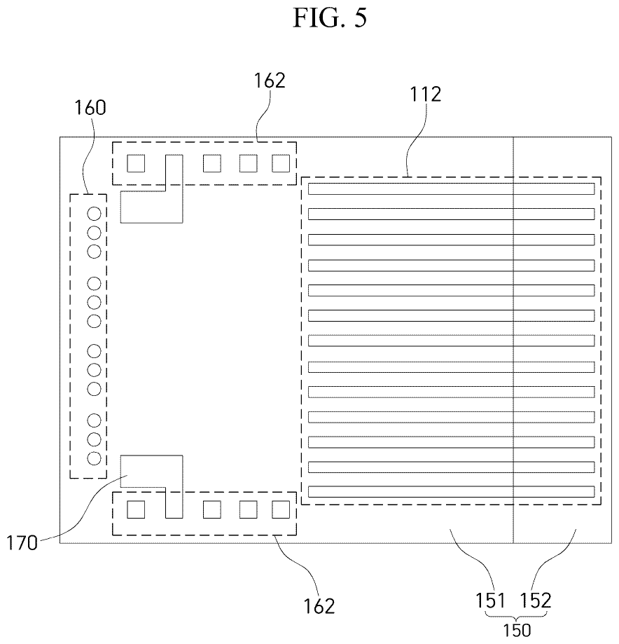

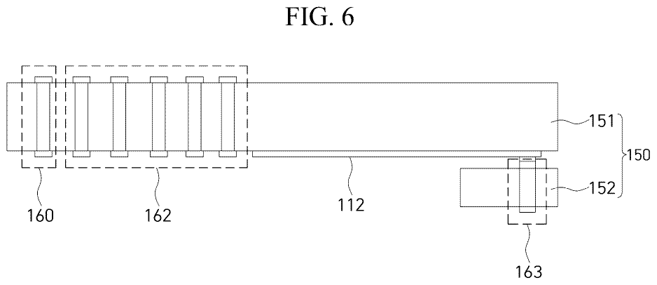

FIG. 5 is a top view of the multi-layer glass interposer mount according to an embodiment. FIG. 6 is a side view of the multi-layer glass interposer mount illustrated in FIG. 5.

Referring to FIGS. 5 to 6, in the multi-layer glass interposer mount 150, the second glass interposer 152 is disposed over the PCB 110, and the first glass interposer 151 is disposed over the second glass interposer 152. The RF through metal electrode 160 is formed on the first glass interposer 151 in order to connect the metal electrode of the optical detector 123 and the input electrode of the pre-amplifier 125. The through metal electrode 162 for DC is formed on the first glass interposer 151 so that the power source for the pre-amplifier 125, the ground, and an electrode for DC, such as an electrode for RSSI monitoring, may be connected to the PCB 110 through bonding wires. In order to share the single layer capacitor for bypass (118 in FIG. 4) and the ground, a ground metal pattern 170 is formed on the first glass interposer 151. In order to electrically connect the output electrode of the pre-amplifier 125 and the input electrode of the signal processing module 140, the transmission line electrode 112 is formed at the bottom of the first glass interposer 151. The RF through electrode 163 is formed in the second glass interposer 152.

The second glass interposer 152 is disposed between the first glass interposer 151 and the PCB 110, and may support the first glass interposer 151. That is, the remaining part of the first glass interposer 151 floats in the air because a part of the first glass interposer 151 is disposed over the pre-amplifier 125. Accordingly, the second glass interposer 152 is disposed in a space between the remaining part of the first glass interposer 151 and the PCB 110 so that the transmission line electrode 112 formed at the bottom of the first glass interposer 151 can be electrically connected to the input electrode of the signal processing module 140 and the remaining part of the first glass interposer 151 also maintains a predetermined interval from the PCB 110. When considering the thickness of the second glass interposer 152 attributable to the soldering of electrodes, it is preferred that the thickness of the second glass interposer 152 is almost the same as or similar to the thickness of the pre-amplifier 125.

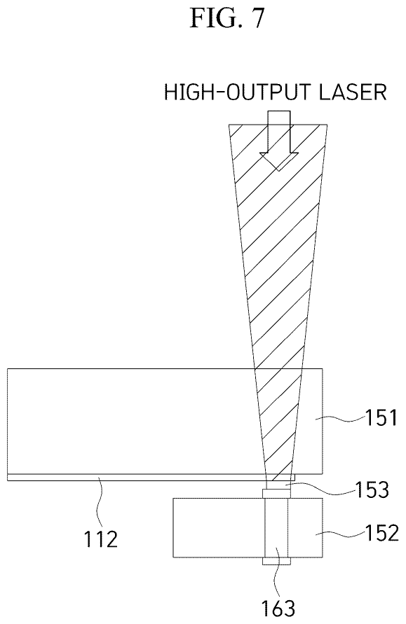

FIG. 7 is a diagram describing a local laser soldering process between the electrodes of the glass interposers using a high-output laser.

The glass interposer has an advantage in that alignment between electrodes and local laser soldering are easy because the glass interposer is transparent and can transmit light, in general. Accordingly, after alignment between the electrodes is optimized by the naked eye or by using an instrument/machine, a solder bump may be locally molten through a soldering process by using a high-output laser, and the electrodes may be then bonded by cooling the solder bump. Such a local laser soldering process can minimize thermal stress and reduce a processing time for soldering, compared to the existing thermal conduction soldering process.

Referring to FIG. 7, for example, after the transmission line electrode 112 at the bottom of the first glass interposer 151 and the RF through electrode 163 on the second glass interposer 152 are made to face each other, the transmission line electrode 112 and the RF through electrode 163 may be bonded by locally radiating a high-output laser from a vertical upper part of the first glass interposer 151 to the solder bump 153 between the transmission line electrode 112 and the RF through electrode 163.

The sequence in which the electrodes of the glass interposers are soldered by using the local laser soldering process and the glass interposer is soldered to the PCB may be various. First, after the electrodes of the first glass interposer and the second glass interposer are soldered by the local laser soldering process, the lower electrode of the second glass interposer may be soldered to the PCB through the existing soldering electrode. Alternatively, after the lower electrode of the second glass interposer is soldered to the PCB through the existing soldering electrode, the upper electrode of the first glass interposer may be soldered on the lower electrode of the second glass interposer by the local laser soldering process. When considering the radiation strength and range of a high-output laser and a refractive index within the glass interposer, a process of soldering the lower electrode of the second glass interposer on the PCB may be performed by radiating a high-output laser from the side of the glass interposer or the top of the glass interposer.

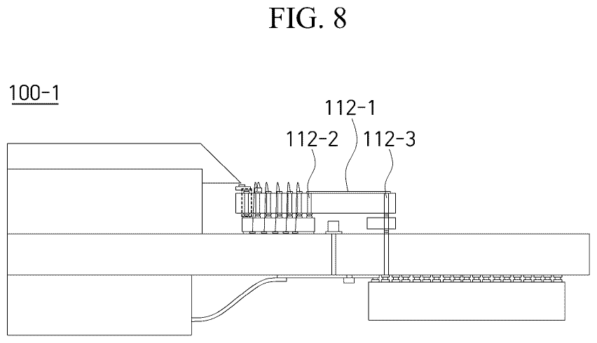

FIG. 8 is a side view of a multi-channel optical transceiver according to another embodiment.

Referring to FIG. 8, unlike in the multi-channel optical transceiver illustrated in FIG. 4, an Rx transmission signal electrode 112-1 may be formed on the first glass interposer 151 of the multi-channel optical transceiver 100 according to another embodiment. In this case, through electrodes 112-2 and 112-3 may be further formed in the first glass interposer 151. The Rx transmission signal electrode 112-1 may be connected to an output stage for the electrical signal of the pre-amplifier 125 through the through electrode 112-2, and may be connected to the through electrode 163 of the second glass interposer through the through electrode 112-3. Even in this case, as illustrated in FIG. 8, the Rx transmission line can minimize an RF transmission loss because the Rx transmission line is spaced apart from the inductor 115.

In the aforementioned embodiments, the components and characteristics of the present disclosure have been combined in a specific form. Each of the components or characteristics may be considered to be optional unless otherwise described explicitly. Each of the components or characteristics may be implemented in a form to be not combined with other components or characteristics. Furthermore, some of the components or the characteristics may be combined to form an embodiment of the present disclosure. The sequence of the operations described in the embodiments of the present disclosure may be changed. Some of the components or characteristics of an embodiment may be included in another embodiment or may be replaced with corresponding components or characteristics of another embodiment. It is evident that an embodiment may be constructed by combining claims not having an explicit citation relation in the claims or may be included as a new claim by amendments after filing an application.

Furthermore, the terms, such as “front”, “rear”, “top”, “upper part”, “below”, “bottom”, “over”, and “under” in the detailed description and the claims, have been used to description purposes, but are not essentially used to describe permanent and relative locations. The terms are understood that they may be exchangeable under a proper environment so that the embodiments of the present disclosure described in this specification may operate in another way other than that illustrated herein or described otherwise, for example.

It will be understood that for the simplicity and clarity of the illustration, elements (or an element) illustrated in the drawings are not essentially drawn at a predetermined ratio. For example, the dimensions of some elements may be enlarged compared to other elements. Furthermore, when considered to be proper, reference numerals may be repeated in the drawings in order to indicate corresponding or similar elements.

It is evident to those skilled in the art that the present disclosure may be embodied in another specific form without departing from the essential characteristics of the present disclosure. Accordingly, the detailed description should not be interpreted as being restrictive, but should be considered as being illustrative in all aspects. The scope of the present disclosure should be determined by rational interpretation of the claims, and all changes within the equivalent range of the present disclosure are included in the scope of the present disclosure.

What is claimed is:

1. A multi-channel optical transceiver, comprising a printed circuit board (PCB), an optical reception module embedded in the PCB and configured to convert a received optical signal into an electrical reception signal, an optical transmission module mounted on a bottom of the PCB and configured to output an electrical transmission signal by modulating the electrical transmission signal into an optical signal, a signal processing module (electrical sub-assembly (ESA)) configured to process the electrical transmission signal and the electrical reception signal, and a flexible printed circuit board (FPCB) configured to electrically connect the signal processing module and the optical transmission module,
wherein the optical reception module comprises:
a pre-amplifier mounted over the PCB;
a glass interposer mount mounted over the pre-amplifier and having a transmission line electrode electrically connected to the signal processing module formed at a bottom thereof; and
an optical detector mounted over the glass interposer mount and configured to detect a received optical signal and to output the detected optical signal to the pre-amplifier by converting the detected optical signal into an electrical reception signal, and
wherein the pre-amplifier transmits the electrical reception signal received from the optical detector to the signal processing module through the transmission line electrode by amplifying the electrical reception signal.

2. The multi-channel optical transceiver of claim 1, wherein the glass interposer mount comprises:
a first glass interposer having a part of a bottom thereof mounted over the pre-amplifier; and
a second glass interposer disposed between another part of the bottom of the first glass interposer and the PCB and configured to support the first glass interposer.

3. The multi-channel optical transceiver of claim 2, wherein:
the transmission line electrode is formed at the bottom of the first glass interposer,
one end of the transmission line electrode is connected to a reception signal output terminal of the pre-amplifier, and
the other end of the transmission line electrode is bonded to a top of a through electrode formed in the second glass interposer.

4. The multi-channel optical transceiver of claim 3, wherein the second glass interposer transmits the electrical reception signal, which is received through the other end of the transmission line electrode, to the signal processing module through a through electrode formed to penetrate the second glass interposer.

5. The multi-channel optical transceiver of claim 4, wherein in the second glass interposer, the pre-amplifier has a thickness corresponding to a height at which the pre-amplifier is bonded to the PCB so that the first glass interposer maintains horizontality with respect to the PCB.

6. The multi-channel optical transceiver of claim 3, wherein the glass interposer mount is formed by locally radiating a high-output laser from a top of the first glass interposer to a solder bump of a bonding part between the other end of the transmission line electrode and a top of a through electrode formed in the second glass interposer.

7. The multi-channel optical transceiver of claim 2, wherein:
the first glass interposer is mounted over the pre-amplifier and is formed to penetrate the pre-amplifier, and
the first glass interposer supplies the pre-amplifier with a power source supplied from a metal electrode formed on the PCB through a through electrode bonded to the pre-amplifier.

8. The multi-channel optical transceiver of claim 1, wherein:
the PCB comprises an inductor mounted thereon, and
the inductor is connected to the electrical transmission signal formed at the bottom of the PCB through a through electrode formed to penetrate the PCB, spaced apart from the transmission line electrode, and mounted on the PCB.

9. A multi-channel optical transceiver, comprising a printed circuit board (PCB), an optical reception module embedded in the PCB and configured to convert a received optical signal into an electrical reception signal, an optical transmission module mounted on a bottom of the PCB and configured to output an electrical transmission signal by modulating the electrical transmission signal into an optical signal, a signal processing module (electrical sub-assembly (ESA)) configured to process the electrical transmission signal and the electrical reception signal, and a flexible printed circuit board (FPCB) configured to electrically connect the signal processing module and the optical transmission module,
wherein the optical reception module comprises:
a pre-amplifier mounted over the PCB;
a glass interposer mount mounted over the pre-amplifier and comprising a transmission line electrode formed over the pre-amplifier and configured to electrically connect the pre-amplifier and the signal processing module; and
an optical detector mounted over the glass interposer mount and configured to detect a received optical signal and to output the detected optical signal to the pre-amplifier by converting the detected optical signal into an electrical reception signal, and
the pre-amplifier transmits the electrical reception signal received from the optical detector to the signal processing module through the transmission line electrode by amplifying the electrical reception signal.

10. The multi-channel optical transceiver of claim 9, wherein the glass interposer mount comprises:
a first glass interposer having a part of a bottom thereof mounted over the pre-amplifier; and
a second glass interposer disposed between another part of the bottom of the first glass interposer and the PCB and configured to support the first glass interposer.

11. The multi-channel optical transceiver of claim 10, wherein:
the first glass interposer has a transmission line electrode formed at a top thereof,
one end of the transmission line electrode is connected to a reception signal output terminal of the pre-amplifier through a through electrode formed in the first glass interposer, and
the other end the transmission line electrode is bonded to the top of the PCB through a through electrode formed in the first glass interposer.

12. The multi-channel optical transceiver of claim 11, wherein the second glass interposer transmits the electrical reception signal, which is received through the other end of the transmission line electrode, to the signal processing module through a through electrode formed to penetrate the second glass interposer.

13. The multi-channel optical transceiver of claim 12, wherein in the second glass interposer, the pre-amplifier has a thickness corresponding to a height at which the pre-amplifier is bonded to the PCB so that the first glass interposer maintains horizontality with respect to the PCB.

14. The multi-channel optical transceiver of claim 10, wherein:
the first glass interposer is mounted over the pre-amplifier and is formed to penetrate the pre-amplifier, and
the first glass interposer supplies the pre-amplifier with a power source supplied from a metal electrode formed on the PCB through a through electrode bonded to the pre-amplifier.

15. The multi-channel optical transceiver of claim 9, wherein:
the PCB comprises an inductor mounted thereon, and
the inductor is connected to the electrical transmission signal formed at the bottom of the PCB through a through electrode formed to penetrate the PCB, spaced apart from the transmission line electrode, and mounted on the PCB.
